(19) United States
(12) Patent Application Publication
(10) Pub. No.: US 2016/0342058 A1
(43) Pub. Date: Nov. 24, 2016

(54) DISPLAY DEVICE HAVING A LIGHT SHIELDING LAYER

(71) Applicant: Samsung Display Co., Ltd., Yongin-si (KR)

(72) Inventors: SEUNGHYUN PARK, Seoul (KR); Junho Song, Seongnam-si (KR); Jeanho Song, Yongin-si (KR)

(21) Appl. No.: 15/016,787

(22) Filed: Feb. 5, 2016

(30) Foreign Application Priority Data
May 20, 2015 (KR) 10-2015-0070450

(51) Int. Cl. G02F 1/1362; G02F 1/1335; G02F 1/1368; G02F 1/1343; H01L 27/12; H01L 29/786

(52) U.S. Cl. CPC G02F 1/136286; H01L 27/124; H01L 29/78633; G02F 1/1368; G02F 1/134309; G02F 1/133514; G02F 1/136209; G02F 2201/40

(57) ABSTRACT

A LCD device includes a first substrate, a second substrate, and a liquid crystal layer between the first substrate and the second substrate. A gate line is disposed on the first substrate. The gate line extends in a first direction. A plurality of data lines extend in a second direction intersecting the first direction. A thin film transistor of a plurality of thin film transistors is disposed at an intersection area between each of the plurality of data lines and the gate line. First, second and third pixel electrodes are sequentially arranged in the first direction. Each of the first, second and third pixel electrodes are respectively connected to one of the thin film transistors. At least two data lines are disposed between the second pixel electrode and the third pixel electrode, and at least one data line is disposed between the second pixel electrode and the first pixel electrode.

### CROSS-REFERENCE TO RELATED APPLICATION

This application claims priority under 35 U.S.C. §119 to Korean Patent Application No. 10-2015-0070450, filed on May 20, 2015, in the Korean Intellectual Property Office (KIPO), the disclosure of which is incorporated by reference herein in its entirety.

1. Technical Field

Exemplary embodiments of the present invention relate to a display device, and more particularly to a display device including a light shielding layer.

2. Discussion of Related Art

Flat panel display (“FPD”) devices may be thin, lightweight, and have low power consumption. Among FPD devices, LCD devices may be used in a wide range of applications such as monitors of laptop computers or desktop computers. LCD devices may have relatively high resolution and relatively high image quality.

LCD devices may include two substrates having electrodes respectively formed on respective opposing surfaces of the two substrates. Liquid crystal materials may be injected between the two substrates, and liquid crystal molecules may be rearranged by an electric field generated by voltages that are applied to the two electrodes, and an image may be displayed based on the transmittance of light which is adjusted by the rearrangement of the liquid crystal molecules.

The LCD device may include a liquid crystal panel injected with a liquid crystal and disposed between the two substrates, a backlight unit disposed below the LCD panel which may be used as a light source, and a driving unit to drive the LCD panel.

In a high-resolution panel, a ratio of an aperture through which light of the LCD panel is transmitted may be decreased.

### SUMMARY

Exemplary embodiments of the present invention may provide a liquid crystal display (“LCD”) device having an increased aperture ratio.

According to an exemplary embodiment of the present invention, a liquid crystal display (LCD) device includes a first substrate, a second substrate, and a liquid crystal layer disposed between the first substrate and the second substrate. A gate line is disposed on a surface of the first substrate. The gate line extends in a first direction. A plurality of data lines extend in a second direction intersecting the first direction. The LCD device includes a plurality of thin film transistors. A thin film transistor of the plurality of thin film transistors is disposed at an intersection area between each of the plurality of data lines and the gate line. A first pixel electrode, a second pixel electrode and a third pixel electrode are sequentially arranged in the first direction. Each of the first, second and third pixel electrodes is respectively connected to one of the thin film transistors of the plurality of thin film transistors. The plurality of data lines includes at least two data lines disposed between the second pixel electrode and the third pixel electrode, and at least one data line disposed between the second pixel electrode and the first pixel electrode.

The liquid crystal display device may include a first color filter, a second color filter and a third color filter. The first color filter may correspond to the first pixel electrode, the second color filter may correspond to the second pixel electrode, and the third color filter may correspond to the third pixel electrode.

The first color filter may be a red color filter, the second color filter may be a blue color filter, and the third color filter may be a green color filter.

The liquid crystal display device may include a fourth pixel electrode disposed adjacent to the third pixel electrode in the first direction.

The liquid crystal display device may include a fourth color filter corresponding to the fourth pixel electrode. The fourth color filter may have a same color as that of the third color filter.

The fourth color filter may be integrally formed with the third color filter.

The first, second, third and fourth color filters may each be disposed on the first substrate.

A gap between the third pixel electrode and the second pixel electrode may be greater than a gap between the third pixel electrode and the fourth pixel electrode.

The liquid crystal display device may include a data light shielding layer disposed on the data line between the second pixel electrode and the first pixel electrode, and a gate light shielding layer intersecting the data light shielding layer. The data light shielding layer may include a first light shielding layer disposed between the first color filter and the second color filter, and a second light shielding layer disposed between the second color filter and the third color filter.

The second light shielding layer may have a width wider than a width of the first light shielding layer.

A light shielding layer may be absent between the third color filter and the fourth color filter.

The first light shielding layer and the second light shielding layer may be disposed on the first substrate.

According to another exemplary embodiment of the present invention, a liquid crystal display (LCD) device includes a first substrate and a second substrate. A gate line is disposed on a surface of the first substrate. The gate line extends in a first direction. A plurality of data lines extend in a second direction intersecting the first direction. The LCD device includes a plurality of thin film transistors. A thin film transistor of the plurality of thin film transistors is disposed at an intersection area between each of the plurality of data lines and the gate line. A first pixel electrode, a second pixel electrode and a third pixel electrode are sequentially arranged in the first direction. Each of the first, second and third pixel electrodes is respectively connected to one of the thin film transistors of the plurality of thin film transistors. The LCD device includes a first color filter, a second color filter and a third color filter. The first color filter corresponds to the first pixel electrode, the second color filter corresponds to the second pixel electrode, and the third color filter corresponds to the third pixel electrode. A gate light shielding layer extends in the first direction and overlaps the gate line. The plurality of data lines includes at least two data lines disposed between the second pixel electrode and the third pixel electrode, and at least one data line disposed between the second pixel electrode and the first pixel electrode.

The first color filter may be disposed adjacent to the third color filter in a second direction. The gate light shielding layer may be disposed between the first color filter and the third color filter.

The third color filter and the first color filter may have different colors.

### BRIEF DESCRIPTION OF THE DRAWINGS

A more complete appreciation of the present invention will become more apparent by describing in detail exemplary embodiments thereof with reference to the accompanying drawings, wherein:

FIG. 1 is a plan view illustrating a liquid crystal display (“LCD”) device according to an exemplary embodiment of the present invention;

FIG. 2 is a view illustrating a pixel array of an LCD device according to an exemplary embodiment of the present invention;

FIG. 3 is a plan view illustrating an array substrate based on the pixel array of FIG. 2;

FIG. 4 is a plan view illustrating a color filter substrate based on the pixel array of FIG. 2;

FIG. 5 is a cross-sectional view taken along line I-I′ of FIG. 3;

FIG. 6 is a plan view illustrating an array substrate according to another exemplary embodiment of the present invention;

FIG. 7 is a plan view illustrating a color filter substrate based on a pixel array of FIG. 6;

FIG. 8 is a plan view illustrating a pixel array structure according another exemplary embodiment of the present invention;

FIG. 9 is a plan view illustrating a display panel according to another exemplary embodiment of the present invention; and

FIG. 10 is a cross-sectional view illustrating a display panel according to another exemplary embodiment of the present invention.

### DETAILED DESCRIPTION

Exemplary embodiments of the present invention will now be described more fully hereinafter with reference to the accompanying drawings in which exemplary embodiments of the present invention are shown.

The present invention may, however, be embodied in many different forms and should not be construed as being limited to the embodiments set forth herein.

It will be understood that, although the terms “first”, “second”, and the like, may be used herein to describe various elements, components, areas, layers and/or sections, these elements, components, areas, layers and/or sections should not be limited by these terms.

Like reference numerals may refer to like elements throughout the specification and drawings.

Hereinafter, exemplary embodiments of the present invention will be described in more detail with reference to the accompanying drawings.

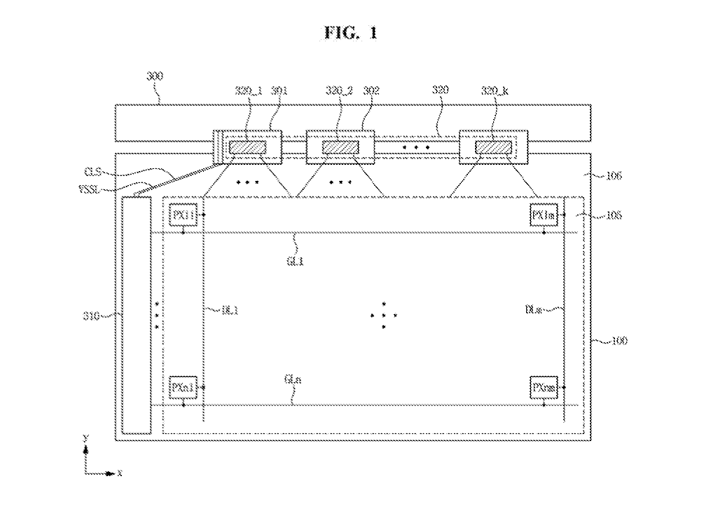

FIG. 1 is a plan view illustrating a liquid crystal display (“LCD”) device according to an exemplary embodiment of the present invention.

Referring to FIG. 1, an LCD device may include a display panel 100, an upper panel, a gate driver 310, a data driver 320, and a driving circuit board 300.

The display panel 100 may include a display area 105 in which a plurality of pixels PX₁₁-PXₙₘ are disposed in a matrix shape, a non-display area 106 surrounding the display area 105, a plurality of gate lines GL1-GLn, a plurality of data lines DL1-DLm intersecting the plurality of gate lines GL1-GLn, a control signal wiring CLS, and an off-voltage line VSSL.

The gate lines GL1-GLn may be connected to the gate driver 310. The gate lines GL1-GLn may sequentially receive gate signals which are sequentially generated from the gate driver 310.

The data lines DL1-DLm may be connected to the data driver 320. The data lines DL1-DLm may receive data voltages having an analog form from the data driver 320.

The pixels PX₁₁-PXₙₘ may be disposed in an intersection area between the gate lines GL1-GLn and the data lines DL1-DLm. The pixels PX₁₁-PXₙₘ may be disposed in “m” number of columns and “n” number of rows intersecting one another. “m” and “n” may be an integer greater than zero.

The pixels PX₁₁-PXₙₘ may be connected to corresponding ones of the gate lines GL1-GLn and corresponding ones of the data lines DL1-DLm, respectively. The pixels may each receive a data voltage from the data line DL in response to a gate signal from the gate line GL. The pixels may each display a gray scale corresponding to the data voltage.

The control signal wiring CLS may be connected to the gate driver 310 through a flexible printed circuit board (FPCB) 301. The control signal wiring CLS may receive control signals from a timing controller. The control signals may be provided to the gate driver 310 through the control signal wiring CLS. The off-voltage line VSSL may be connected to the gate driver 310 through the FPCB 301. The FPCB 301 may be a leftmost FPCB among a plurality of FPCBs (e.g., FPCBs 301 and 302). The off-voltage line VSSL may receive an off-voltage signal from a voltage generator which may be dispsoed on a driving circuit board. The off-voltage signal may be provided to the gate driver 310 through the off-voltage line VSSL.

The gate driver 310 may be disposed on the non-display area 106 adjacent to a side of the display area 105. The gate driver 310 may be disposed on the non-display area 106 adjacent to a left side of the display area 105. The gate driver 310 may sequentially generate gate signals using the control signals provided through the control signal wiring CLS, and may provide the generated gate signals to the gate lines GL1-GLn. The gate lines GL1-GLn may be sequentially driven from an uppermost gate line to a lowermost gate line.

The data driver 320 may receive data signals from the timing controller, and may generate analog data voltages corresponding to the data signals. The data driver 320 may provide the data voltages to the pixels PX₁₁-PXₙₘ through the data lines DL1-DLm. The data driver 320 may include a plurality of data driver chips 320_1-320_k. “k” may be an integer greater than zero and less than “m”. The data driver chips 320_1-320_k may be disposed on corresponding flexible printed circuit boards, respectively. The data driver chips 320_1-320_k may be connected between the driving circuit board 300 and a portion of the non-display area 106 adjacent to an upper portion of the display area 105.

The data driver chips 320_1-320 k may be disposed on the portion of the non-display area 106 adjacent to the upper portion of the display area 105, in a chip-on-glass (COG) manner.

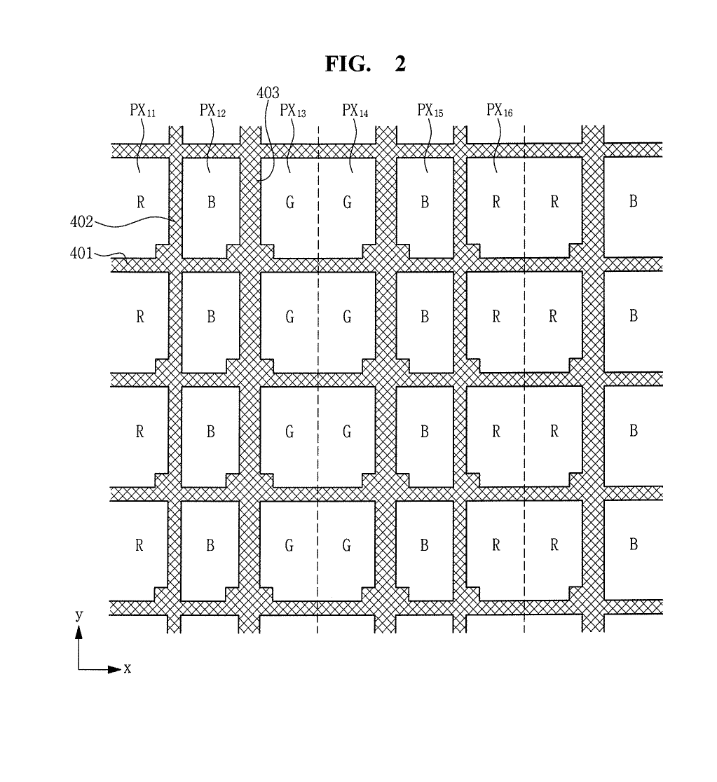

FIG. 2 is a view illustrating a pixel array of an LCD device according to an exemplary embodiment of the present invention.

The display panel 100 may include a plurality of pixels, each of which may display one of red, blue, and green light. Each pixel may include a color filter through which light (for example, red light, green light, or blue light) having a predetermined wavelength is transmitted. The display device according to an exemplary embodiment of the present invention may display various colors by adjusting the luminance of three adjacent pixels displaying respective colors. Depending on the pixel array, color mixing may occur in which different colors of adjacent pixels are seen to be mixed with one another. Light shielding layers 401, 402, and 403 may be disposed in the pixel array and may reduce or prevent an occurrence of color mixing between pixels. The light shielding layers 401, 402, and 403 may cover non-display elements such as the gate line GL, the data line DL, and a thin film transistor which are disposed on an array substrate. The light shielding layers 401, 402, and 403 may include a gate light shielding layer 401 that extends in a first direction (e.g., along direction X) along the gate line GL, a data light shielding layer including a first light shielding layer 402 and a second light shielding layer 403 that extend in a second direction along the data line DL. The light shielding layers 401, 402, and 403 may form a lattice shape in which the gate light shielding layer 401 and the data light shielding layer 402 intersect one another. The gate light shielding layer 401 and the data light shielding layer 402 intersecting each other may be referred to as a black matrix.

The display panel 100 according to an exemplary embodiment of the present invention may include a pixel array structure in which a pixel array including a red pixel PX₁₁, a blue pixel PX₁₂ and a green pixel PX₁₃, and a pixel array including a green pixel PX₁₄, a blue pixel PX₁₅ and a red pixel PX₁₆ are alternately disposed.

According to an exemplary embodiment of the present invention, green or red pixels may be disposed to be adjacent to one another in the first direction (e.g., direction X), and the light shielding layer may be omitted between the adjacent green or red pixels.

Since a blue color light and a green color light may be relatively more like to result in color mixing, the second light shielding layer 403 between a blue pixel and a green pixel may have a width wider than a width of the first light shielding layer 402 between a red pixel and a blue pixel. At least one light shielding layer may extend on to an area overlapping the thin film transistor and thus external light reflected by the thin film transistor may be reduced or prevented.

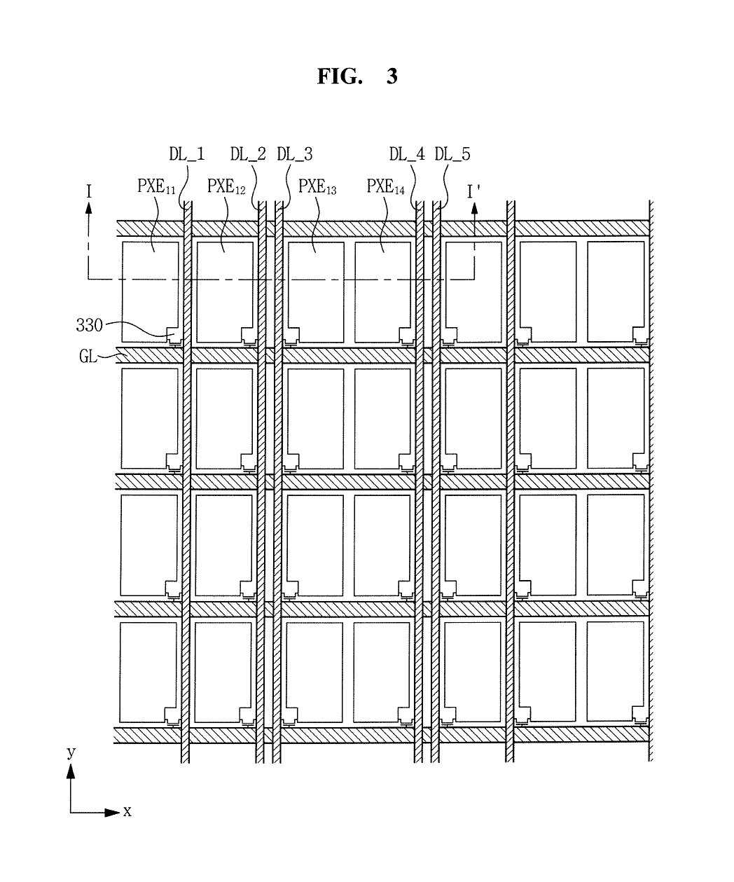

FIG. 3 is a plan view illustrating an array substrate based on the pixel array of FIG. 2.

An array structure including data lines DL according to an exemplary embodiment of the present invention will be described in more detail with reference to FIG. 3.

The gate line GL and the data line DL may be connected to a thin film transistor 330 at an intersection area between the gate line GL and the data line DL. The thin film transistor 330 may be connected to a pixel electrode PXE.

Based on a pixel array pattern, a first data line DL_1 between a pixel electrode PXE₁₁ of the red pixel PX₁₁ and a pixel electrode PXE₁₂ of the blue pixel PX₁₂ may be connected to the thin film transistor 330 of the red pixel PX₁₁. Second and third data lines DL_2 and DL_3 may be disposed between the pixel electrode PXE₁₂ of the blue pixel PX₁₂ and a pixel electrode PXE₁₃ of the green pixel PX₁₃. The data lines DL_2 and DL_3 may be connected to thin film transistors 330 of the blue pixel PX₁₂ and the green pixel PX₁₃, respectively.

A plurality of data lines DL_4 and DL_5 may be disposed between a pixel electrode PXE₁₄ of the green pixel PX₁₄ adjacent to the green pixel electrode PXE₁₃ and a pixel electrode PXE₁₅ of the blue pixel PX₁₅. The data lines DL_4 and DL_5 may be connected to thin film transistors 330 of the green pixel PX₁₄ and the blue pixel PX₁₅, respectively. The array pattern of the data lines DL may be repeated in conformity with the pixel array pattern.

The data line DL may be omitted between consecutive green or red pixels. Since adjacent same color pixels, green or red, may be separately driven, corresponding pixel electrodes of the adjacent same color pixels might not be electrically connected.

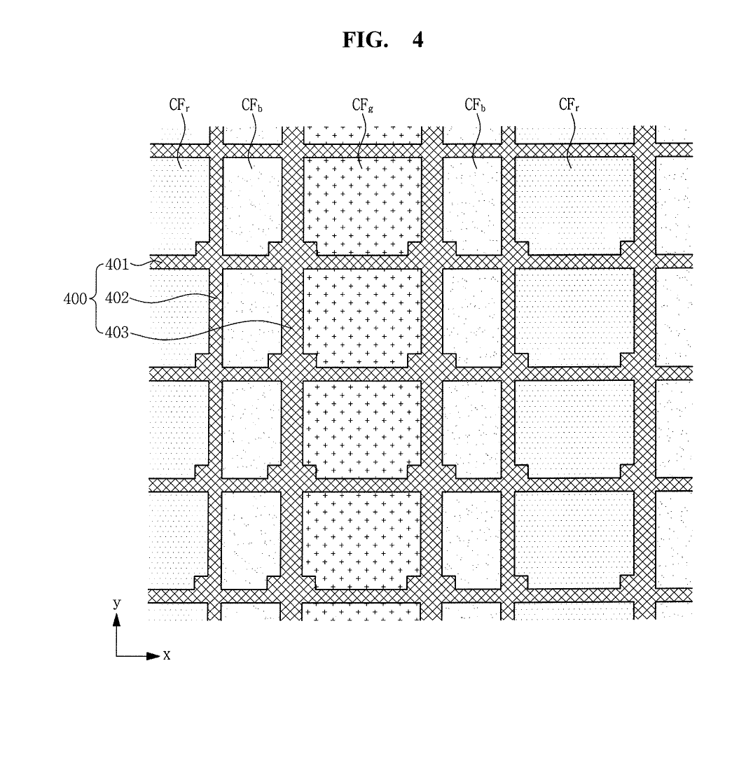

FIG. 4 is a plan view illustrating a color filter substrate based on the pixel array of FIG. 2.

A light shielding layer 400 (e.g., including light shielding layers 401, 402 and 403) according to an exemplary embodiment of the present invention will be described in more detail below with reference to FIG. 4.

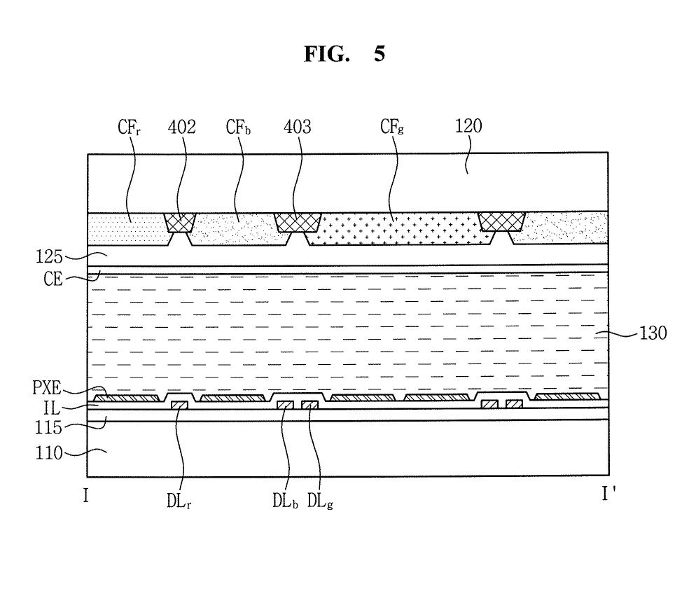

A color filter substrate, which may also be referred to as an upper substrate, may be different than the array substrate illustrated in FIG. 3. The color filter substrate may include a plurality of color filters CF (e.g., color filters CFᵣ, CF_{b}, and CF_{g}) which may be disposed in a matrix shape, and which may correspond to colors displayed by respective pixels. A planarization layer 125 (see, e.g., FIG. 5) may be disposed over substantially an entire surface of the light shielding layer 400 and the color filters CF, and a transparent common electrode CE (see, e.g., FIG. 5) may be disposed on the planarization layer 125.

The light shielding layer 400 may be formed by spraying an organic ink, or patterning a metal layer through a photolithography process. The light shielding layer 400 may include an organic light shielding layer (e.g., a black matrix) including chromium (Cr), chromium oxide (CrOₓ), or a resin. The organic light shielding layer may include a colored organic resin, for example, an acryl, epoxy or polyimide resin including one of carbon black and a black pigment.

The light shielding layer 400 according to an exemplary embodiment of the present invention may include the gate light shielding layer 401 overlapping the gate line GL and the data light shielding layer 402 overlapping the data line DL. The light shielding layer 400 may extend on to an area in which the thin film transistor is disposed.

The data light shielding layer may include the first light shielding layer 402 and the second light shielding layer 403. The first light shielding layer 402 may overlap the data line DL_1. The second light shielding layer 403 may overlap the plurality of data lines DL_2 and DL_3. The second light shielding layer 403 corresponds to the plurality of data lines DL to have a wider width than that of the first light shielding layer 402.

The light shielding layer 400 may be omitted in an area between adjacent pixels displaying the same color (e.g., adjacent red or green pixels). In the case of adjacent same color pixels, respective color filters CF of the adjacent same color pixels may be integrally formed with the adjacent same color pixels (see, e.g., color filters CF_{g} and CF_{F}).

The gate light shielding layer 401 may be disposed on the gate line GL extending in the first direction.

FIG. 5 is a cross-sectional view taken along line I-I′ of FIG. 3.

The LCD device according to an exemplary embodiment of the present invention may include a liquid crystal panel including the array substrate and the color filter substrate disposed on opposite sides of a liquid crystal layer 130 of the liquid crystal panel.

The liquid crystal layer 130 may be disposed in a gap between the array substrate and the color filter substrate. The liquid crystal layer 130 may be sealed by a sealing member disposed along an outermost edge portion of the liquid crystal layer 130 between the array substrate and the color filter substrate.

A backlight unit including a light source may be disposed on a lower surface of the LCD device.

The array substrate may include a plurality of gate lines GL extending in the first direction, a gate insulating layer 115 insulating the gate line, and a plurality of data lines DL (e.g., data lines DLᵣ, DL_{b} and DL_{g}) disposed on the gate insulating layer 115 and extending in a second direction (e.g., a Y direction)_intersecting the first direction. A red pixel data line DLr may be disposed between a red pixel and a blue pixel. A blue pixel data line DL_{b} and a green pixel data line DL_{g} may be disposed in parallel to one another between the blue pixel and a green pixel. The blue pixel data line DL_{b} and the green pixel data line DL_{g} may provide data voltages to respective pixel electrodes PXE of the blue pixel and the green pixel. A protection layer IL may be disposed on the data line DL. The pixel electrode PXE may be disposed on the protection layer IL.

The color filter substrate may be disposed on a second substrate 120, a plurality of color filters CFᵣ, CF_{b}, and CF_{g} corresponding to respective pixel electrodes PXE of the array substrate, and the light shielding layer 400 including the gate light shielding layer 401 (see, e.g., FIG. 4) and the data light shielding layer 402 and the second light shielding layer 403. The second substrate 120 may be a transparent substrate. The planarization layer 125 and the common electrode CE which may compensate for a step difference may be disposed on the color filter CF and the light shielding layer 400. The color filers may be disposed in a sequence of red, blue, green, green, blue, and red, corresponding to the color sequence in the pixel array. The light shielding layer 400 may be disposed between different color filters CF. When adjacent pixels have the same color filters CF, the adjacent color filters CF may be integrally formed.

The second light shielding layer 403 may be disposed above the blue and green pixel data lines DL_{b} and DL_{g} and may overlap the blue and green pixel data lines DL_{b} and DL_{g}, and may have a relatively wide width as compared to that of the first light shielding layer 402 such that reflection of external light caused by the data line DL may be blocked.

Although a pixel having a predetermined color may be described by way of example in exemplary embodiments of the present invention, the color of each pixel may vary based on characteristics of the display panel and a pixel design.

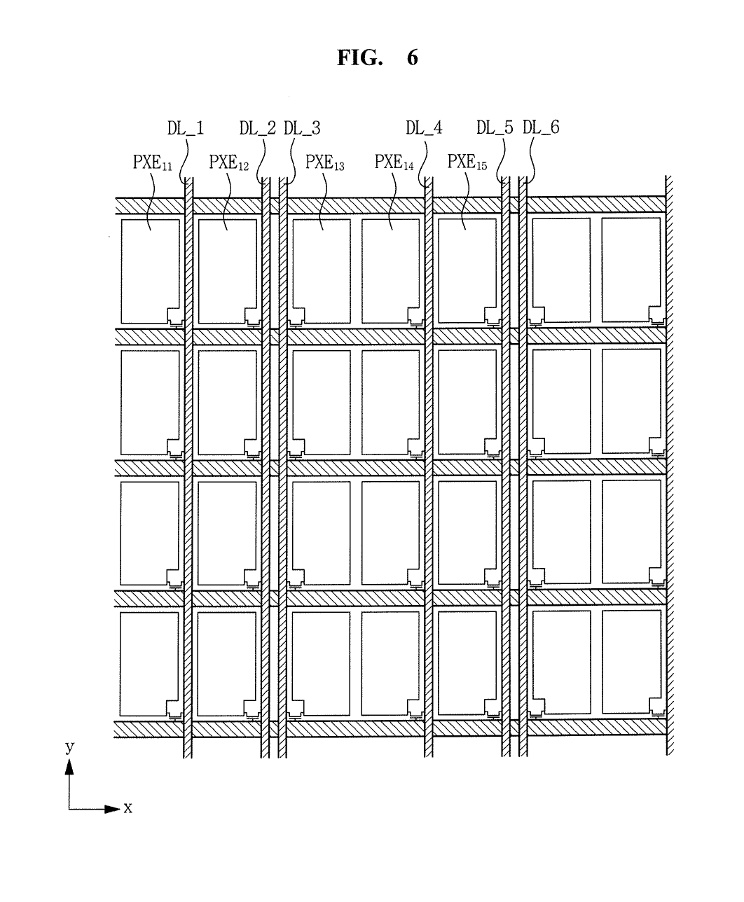

FIG. 6 is a plan view illustrating an array substrate according to another exemplary embodiment of the present invention.

An array substrate with a modified array of data lines DL according to an exemplary embodiment of the present invention will be described in more detail below with reference to FIG. 6.

The array substrate of FIG. 6 may have the same pixel array pattern as that of the display device of FIG. 2.

The data line DL_1 between the pixel electrode PXE₁₁ of the red pixel PX₁₁ and the pixel electrode PXE₁₂ of the blue pixel PX₁₂ may be connected to the red pixel PX₁₁ disposed at a side of the data line DL_1. A plurality of parallel data lines DL_2 and DL_3 may be disposed between the pixel electrode PXE₁₂ of the blue pixel PX₁₂ and a pixel electrode PXE₁₃ of the green pixel PX₁₃. The data lines DL_2 and DL_3 may be connected to the blue pixel PX₁₂ and the green pixel PX₁₃ that are disposed at opposite sides of the data lines DL_2 and DL_3, respectively. A data line DL_4 may be disposed between the pixel electrode PXE₁₄ of the green pixel PX₁₄ and the pixel electrode PXE₁₅ of the blue pixel PX₁₅ may be connected to the green pixel PX₁₄. The pixel electrodes PXE₁₄ and PXE₁₅ may be consecutively disposed in a direction in which the gate line GL extends. A plurality of parallel data lines DL_5 and DL_6 may be disposed between the pixel electrode PXE₁₅ of the blue pixel PX₁₅ and the pixel electrode PXE₁₆ of the red pixel PX₁₆. The data lines DL_5 and DL_6 may be connected to the blue pixel PX₁₅ and the red pixel PX₁₆, respectively.

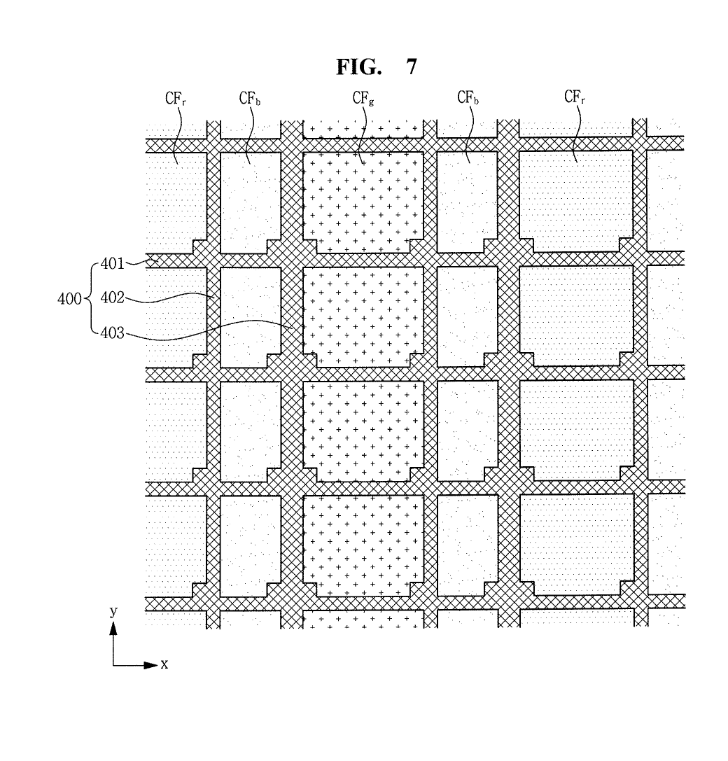

FIG. 7 is a plan view illustrating a color filter substrate based on a pixel array of FIG. 6.

Referring to FIGS. 6 and 7, the first light shielding layer 402 according to an exemplary embodiment of the present invention may overlap the data line DL_1, and the second light shielding layer 403 may overlap the plurality of data lines DL_2 and DL_3. The first light shielding layer 402 may overlap the data line DL_1 between the pixel electrode PXE₁₁ of the red pixel PX₁₁ and the pixel electrode PXE₁₂ of the blue pixel PX₁₂, and the second light shielding layer 403 may overlap the plurality of data lines DL_2 and DL_3 between the pixel electrode PXE₁₂ of the blue pixel PX₁₂ and the pixel electrode PXE₁₃ of the green pixel PX₁₃. The second light shielding layer 403 may have a width wider than that of the first light shielding layer 402 and may overlap the plurality of data lines DL.

Based on the array pattern of the data lines DL and the array of the light shielding layers 402 and 403 overlapping the data lines DL, a data light shielding layer having a relatively wide width and a data light shielding layer having a relatively small width may be alternately disposed on the color filter substrate.

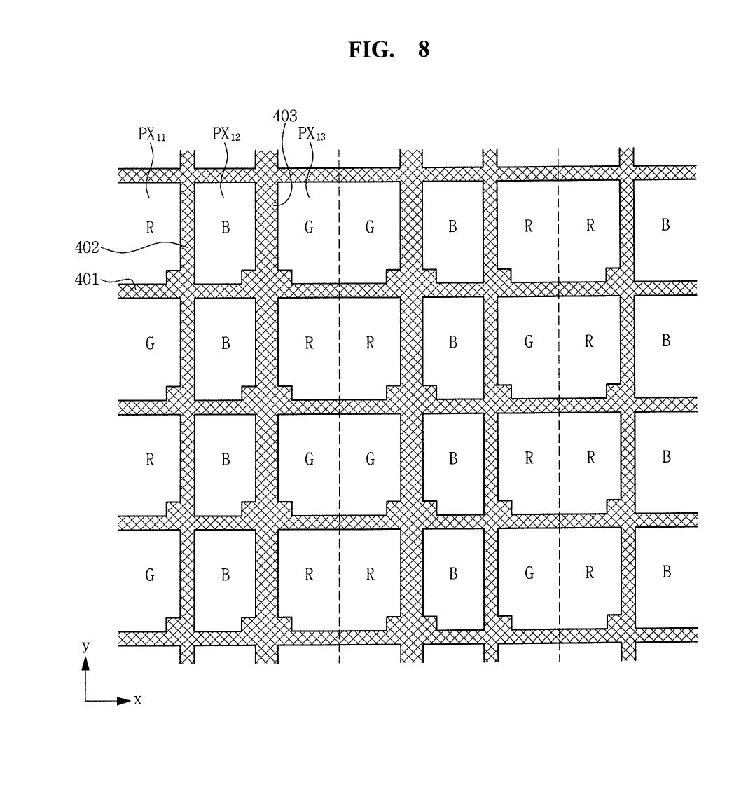

FIG. 8 is a plan view illustrating a pixel array structure according to another exemplary embodiment of the present invention.

Referring to FIG. 8, the display panel according to an exemplary embodiment of the present invention may include the pixel array pattern. The pixel array pattern may include a first row in which red, blue and green pixels PX₁₁, PX₁₂ and PX₁₃ are sequentially disposed, and subsequently thereto, green, blue and red pixels PX₁₄, PX₁₅ and PX₁₆ are sequentially disposed in a first direction. The pixel array pattern may be continuously repeated in the first direction, as desired.

The pixel array pattern may include second row including a pixel array different from the pixel array in the first row. For example, the display panel has according to an exemplary embodiment of the present invention may include a pixel array pattern in the second row in which green, blue and red pixels PX₂₁, PX₂₂ and PX₂₃ are sequentially disposed, and subsequently thereto, red, blue and green pixels PX₂₄, PX₂₅ and PX₂₆ are sequentially disposed.

When green pixels are disposed adjacent to one another in the first row, adjacent red pixels may be disposed to be adjacent, in a second direction, to the green pixels in the first row. The display panel may include the pixel array in which the green pixels and the red pixels are alternately disposed in the second direction. The gate light shielding layer 401 may be disposed between the red pixels and the green pixels disposed in the second direction, and thus, an occurrence of color mixing of the light transmitted by the pixels may be reduced or prevented.

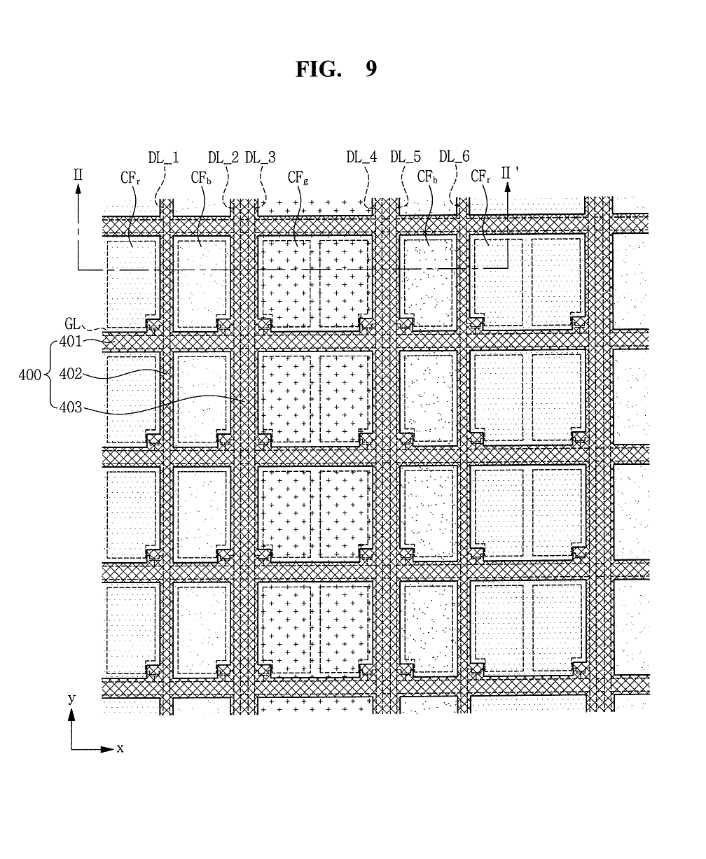

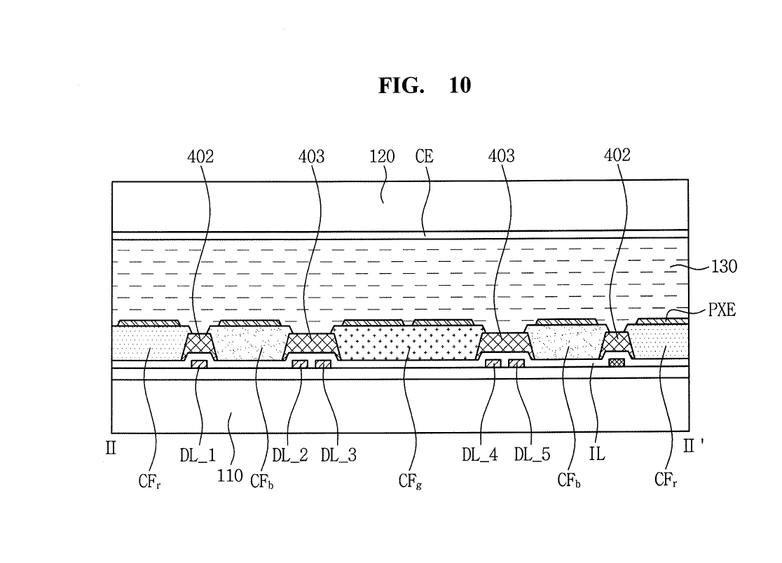

FIG. 9 is a plan view illustrating a display panel according to another exemplary embodiment of the present invention. FIG. 10 is a cross-sectional view illustrating a display panel according to another exemplary embodiment of the present invention.

A layer structure below a light shielding layer 400 according to another exemplary embodiment of the present invention will be described with reference to FIGS. 9 and 10. Referring to FIGS. 9 and 10, the array substrate according another exemplary embodiment of the present invention may include the gate line GL, the gate insulating layer 115, the data line DL, and the protection layer IL, disposed on a first substrate 110. The light shielding layer 400 and the color filter CF may be disposed on the protection layer IL. The light shielding layer 400 may be selectively disposed on the data line DL, the gate line GL, and a thin film transistor. The second light shielding layer 403 may be disposed on data lines DL_3 and DL_4 which may be adjacently parallel to one another. The second light shielding layer 403 may be formed in a manner similar to that forming the first light shielding layer 402, and may have a relatively wide width. The gate light shielding layer 401 may be disposed on the gate line GL.

Color filters CFᵣ, CF_{b}, and CF_{g} may be disposed on a display area of the first substrate 110 which is not covered by the light shielding layer 400. For example, in a case of adjacent green pixels, respective color filters CF_{g} of the adjacent green pixels may be integrally formed.

The pixel electrode PXE that receives the data voltage representing a gray scale of the pixel may be disposed on the color filter CF. The pixel electrode PXE may be connected, through a via hole, to the thin film transistor which is connected to the gate line GL and the data line DL.

The second substrate 120 which may be disposed on an opposite side of the display panel from the first substrate 110 may include a common electrode CE. The liquid crystal layer 130 may be disposed between the first substrate 110 and the second substrate 120. According to an exemplary embodiment of the present invention, the light shielding layer 400 may be disposed on the first substrate 110. According to a exemplary embodiments of the present invention, the light shielding layer 400 may be disposed on the second substrate 120. A portion of the second light shielding layer 403 may have a relatively large height and may maintain a distance between the first and second substrates 110 and 120.

The LCD display device according to exemplary embodiments of the present invention may have relatively low power consumption and relatively high luminance by the pixel array structure in which portions of the pixel area covered by the data line and the light shielding layer are reduced.

While the present invention has been shown and described with reference to the exemplary embodiments thereof, it will be apparent to those of ordinary skill in the art that various changes in form and detail may be made thereto without departing from the spirit and scope of the present invention.

What is claimed is:

1. A liquid crystal display (LCD) device comprising:
a first substrate, a second substrate, and a liquid crystal layer disposed between the first substrate and the second substrate;
a gate line disposed on a surface of the first substrate, wherein the gate line extends in a first direction;
a plurality of data lines extending in a second direction intersecting the first direction;
a plurality of thin film transistor, wherein a thin film transistor of the plurality of thin film transistors is disposed at an intersection area between each of the plurality of data lines and the gate line; and
a first pixel electrode, a second pixel electrode and a third pixel electrode sequentially arranged in the first direction, wherein each of the first, second and third pixel electrodes is respectively connected to one of the thin film transistors of the plurality of thin film transistors, and
wherein the plurality of data lines comprises at least two data lines disposed between the second pixel electrode and the third pixel electrode, and at least one data line disposed between the second pixel electrode and the first pixel electrode.

2. The liquid crystal display device of claim 1, further comprising a first color filter, a second color filter and a third color filter, wherein the first color filter corresponds to the first pixel electrode, the second color filter corresponds to the second pixel electrode, and the third color filter corresponds to the third pixel electrode.

3. The liquid crystal display device of claim 2, wherein the first color filter, the second color filter and third color filter have different colors from one another, including red, blue and green.

4. The liquid crystal display device of claim 3, further comprising a fourth pixel electrode disposed adjacent to the third pixel electrode in the first direction.

5. The liquid crystal display device of claim 4, further comprising a fourth color filter corresponding to the fourth pixel electrode, wherein the fourth color filter has a same color as that of the third color filter.

6. The liquid crystal display device of claim 5, wherein the fourth color filter is integrally formed with the third color filter.

7. The liquid crystal display device of claim 5, wherein the first, second, third and fourth color filters are each disposed on the first substrate.

8. The liquid crystal display device of claim 5, wherein a gap between the third pixel electrode and the second pixel electrode is greater than a gap between the third pixel electrode and the fourth pixel electrode.

9. The liquid crystal display device of claim 5, further comprising a data light shielding layer disposed on the data line between the second pixel electrode and the first pixel electrode, and a gate light shielding layer intersecting the data light shielding layer,
wherein the data light shielding layer comprises:
a first light shielding layer disposed between the first color filter and the second color filter; and
a second light shielding layer disposed between the second color filter and the third color filter.

10. The liquid crystal display device of claim 9, wherein the second light shielding layer has a width wider than a width of the first light shielding layer.

11. The liquid crystal display device of claim 10, wherein a light shielding layer is absent between the third color filter and the fourth color filter.

12. The liquid crystal display device of claim 9, wherein the first light shielding layer and the second light shielding layer are disposed on the first substrate.

13. A liquid crystal display (LCD) device comprising:
a first substrate and a second substrate;
a gate line disposed on a surface of the first substrate, wherein the gate line extends in a first direction;
a plurality of data lines extending in a second direction intersecting the first direction;
a plurality of thin film transistors, wherein a thin film transistor of the plurality of thin film transistors is disposed at an intersection area between each of the plurality of data lines and the gate line;
a first pixel electrode, a second pixel electrode and a third pixel electrode sequentially arranged in the first direction, wherein each of the first, second and third pixel electrodes is respectively connected to one of the thin film transistors of the plurality of thin film transistors;
a first color filter, a second color filter, and a third color filter, wherein the first color filter corresponds to the first pixel electrode, the second color filter corresponds to the second pixel electrode, and the third color filter corresponds to the third pixel electrode; and
a gate light shielding layer extending in the first direction and overlapping the gate line,
wherein the plurality of data lines comprises at least two data lines disposed between the second pixel electrode and the third pixel electrode, and at least one data line disposed between the second pixel electrode and the first pixel electrode.

14. The liquid crystal display device of claim 13, wherein the first color filter is disposed adjacent to the third color filter in a second direction, and wherein the gate light shielding layer is disposed between the first color filter and the third color filter.

15. The liquid crystal display device of claim 14, wherein the third color filter and the first color filter have different colors.
